(19) United States
(12) Patent Application Publication
(10) Pub. No.: US 2021/0141116 A1
(43) Pub. Date: May 13, 2021

(54) DETECTOR FOR SMALL METAL OBJECT INCLUDING GEOMAGNETIC SENSORS

(71) Applicant: MAGO technology Co., Ltd., Seoul (KR)

(72) Inventor: Jung A KIM, Seoul (KR)

(73) Assignee: MAGO technology Co., Ltd., Seoul (KR)

(21) Appl. No.: 16/682,559

(22) Filed: Nov. 13, 2019

(51) Int. Cl. G01V 3/08; G01R 33/09

(52) U.S. Cl. CPC G01V 3/08; G01R 33/09

(57) ABSTRACT

Provided is a detector for a small metal object using geomagnetic sensors. A plurality of magnetoresistive element pairs is disposed in a detecting area to detect a minute change in a magnetic field caused by a small ferromagnetic material, such as a handgun, in the detecting area. The magnetoresistive element pairs are disposed between a first point and a second point of the detecting area, such that a bridge offset and a measurement axis offset are provided, so as to effectively detect the minute change in the magnetic field.

### BACKGROUND OF THE INVENTION

### Field of the Invention

The present invention relates generally to a detector able to detect a movement of a small metal object by using a plurality of geomagnetic sensors and, more particularly, to a detector able to detect a minute change in a magnetic field caused by a small metal object by removing the influence of movements of vehicles, such as automobiles, trucks, or buses.

### Description of the Related Art

A geomagnetic sensor or sensor of the earth's magnetic field is a sensor detecting a change in the geomagnetic field caused by a ferromagnetic material using a magnetoresistive element, the resistance value of which changes in response to a change in a magnetic field. Such a geomagnetic sensor is used to detect metal or the like. The magnetoresistive element used in the geomagnetic sensor may typically be an anisotropic magnetoresistive (AMR) element, a giant magnetoresistive (GMR) element, or the like.

FIG. 1A is a schematic view illustrating a conventional geomagnetic sensor in the form of an AMR bridge, and FIG. 1 is a schematic view illustrating a geomagnetic sensor circuit including the geomagnetic sensor illustrated in FIG. 1A.

The geomagnetic sensor includes four magnetoresistive elements representatively referred to as four resistors R1, R2, R3, and R4 arranged in the form of a Wheatstone bridge. The resistance values of the four magnetoresistive elements change due to the magnetoresistance effect in response to a change in a magnetic field. In general, in the geomagnetic sensor as illustrated in FIG. 1A, resistances R2 and R3 decrease (or increase) with increases (or decreases) in resistances R1 and R4 in response to a change in a magnetic field at a center point (i.e. a measurement point), so that voltages at connection nodes Out+ and Out−, serving as output terminals, are changed due to the distribution of voltage. Accordingly, as illustrated in FIG. 1B, a predetermined voltage is applied between a terminal Vb of the geomagnetic sensor U1 and the ground terminal GND, and output voltages of Out+ and Out− are differentially amplified using a differential amplifier U2.

To detect a ferromagnetic material, such as a metal, using the geomagnetic sensor, a plurality of problems must be solved. First, geomagnetic sensors commercially available at present typically have a sensitivity level of about 3 mV/Gauss, although having been improved from previous geomagnetic sensors. Furthermore, the magnitude of a signal decreases in reverse proportion to the third power of a detection distance. Accordingly, it is essentially difficult to detect a change in the magnetic field at a relatively-long distance of 1 meter or more, unless the change of the magnetic field is significantly large. For these reasons, a plurality of problems should be solved to detect a movement of a metal object at a predetermined distance using the geomagnetic sensor.

For example, a case in which a movement of a small metal object, such as a handgun, is to be detected within a distance of 1 to 2 meters may be considered. Since a change in the magnetic field caused by the small metal object is minute, the change in the magnetic field must be amplified at a significantly great amplification factor, so that the change in the magnetic field occurring at the distance of 1 to 2 meters can be detected. However, the design for electrical amplification is limited, due to the nonlinearity of a magnetic element, noise, Barkhausen effect, and the like. For these reasons, it is substantially impossible to detect a movement of a small metal object at a distance of 1 to 2 meters using the geomagnetic sensor in the related art.

In addition, while a small metal object is being detected in an environment, such as an urban area, there may be a movement of a large metal object, such as a bus or an elevator. In such a case, even when the large metal object is at a distance of 20 to 30 meters, a change in the magnetic field caused by the large metal object may be detected more significantly than that by the small metal object. Accordingly, it is significantly difficult to separately recognize the movement of the small metal object.

In summary, in order to detect a small metal object, such as a handgun, at a distance of 1 to 2 meters, a plurality of problems to be solved will be described below.

(1) A change in the geomagnetic field is proportional to the size of an object moving in the geomagnetic field. To detect a small ferromagnetic material having the size of a handgun at a distance of about 1.5 meter, an ultra-precision magnetic sensor having a resolution of 10⁻¹⁵ of the magnitude of the geomagnetic field is required.

(2) A large ferromagnetic material, such as a bus or an elevator, may distort the geomagnetic field at a significantly long distance of 20 to 30 meters. Therefore, when there is a movement of a large ferromagnetic material in the surrounding area, the movement may act as a significant level of noise, and thus, a movement of a small object, such as a handgun, cannot be detected even when an ultra-precision magnetic sensor is used.

(3) Since the geomagnetic field changes by 8% in a year and 2% to 3% in a day instead of being completely fixed, the ability of distinguish a change in the geomagnetic field itself from a change in the geomagnetic field caused by a movement of a small object is required.

The information disclosed in the Background of the Invention section is only for the enhancement of understanding of the background of the invention, and should not be taken as an acknowledgment or as any form of suggestion that this information forms a prior art that would already be known to a person skilled in the art.

### SUMMARY OF THE INVENTION

Accordingly, the present invention has been made keeping in mind the above problems occurring in the related art, and the present invention proposes a detector able to detect a movement of a small metal object, such as a handgun, by using a plurality of geomagnetic sensors.

Also provided is a detector able to detect a minute change in a magnetic field caused by a small metal object by removing the influence of movements of vehicles, such as automobiles, trucks, or buses, or a change in the geomagnetic field itself.

In order to achieve the above objective, according to one aspect of the present invention, a detector including geomagnetic sensors according to the invention proposes a space offset differential amplification structure for detecting a minute change in a magnetic field.

The detector according to the invention may be disposed at a first point and a second point within a width of 2 meters to detect a ferromagnetic material passing through a detecting area between the first point and the second point. The detector according to the invention includes first to fourth magnetoresistive element pairs respectively comprised of two magnetoresistive elements connected in series between an operating voltage (VCC) and a ground (GND) and a detecting module.

The first pair is disposed at the first point such that a measurement axis thereof is in a direction of +x axis directed to the second point, the second pair is disposed at the second point such that a measurement axis thereof is in a direction of −x axis, the third pair is disposed at the first point such that a measurement axis thereof is in a direction of +y axis perpendicular to the +x axis, and the fourth pair is disposed at the second point such that a measurement axis thereof is in a direction of −y axis perpendicular to the −x axis. If there is a change in outputs of the first to fourth pairs, the detecting module determines that there is a ferromagnetic material moving in the detecting area.

According to an embodiment, the detecting module may include: a first differential amplifier differentially amplifying voltages of output nodes of the first pair and the second pair; a second differential amplifier differentially amplifying voltages of output nodes of the third pair and the fourth pair; and an analyzer determining that there is the ferromagnetic material moving in the detecting area when outputs of the first differential amplifier and the second differential amplifier are detected.

According to another embodiment, the analyzer may determine that there is the ferromagnetic material moving in the detecting area when a Euclidean norm obtained from outputs of the first differential amplifier and the second differential amplifier is equal to or greater than a predetermined reference value.

According to another embodiment, the detecting module may further include a common mode detector detecting a common mode when signals having the same magnitude and the same sign are output from the first pair and the second pair. Here, the common mode may be a state in which a change in a magnetic field caused by a movement of a large ferromagnetic material outside of the detecting area is acting on the detecting area.

Sensor Module Including Axis Magnetoresistive Element Pairs

The detector according to the invention may further include a fifth magnetoresistive element pair and a sixth magnetoresistive element pair in addition to the four magnetoresistive element pairs and a third differential amplifier processing outputs of the fifth pair and the sixth pair. The fifth pair is disposed at the first point such that a measurement axis thereof is in a direction of +z axis perpendicular to the +x axis and the +y axis, and the sixth pair is disposed at the second point such that a measurement axis thereof is in a direction of −z axis. The third differential amplifier differentially amplifies voltages of output nodes of the fifth pair and the sixth pair. Here, the analyzer may determine that there is a ferromagnetic material moving in the detecting area even when the outputs of at least 2 differential amplifiers out of the 3 amplifiers are detected. For example, when the outputs of the first differential amplifier and the third differential amplifier or all of the outputs of the first differential amplifier, the second differential amplifier, and the third differential amplifier are detected, the analyzer may determine that there is a ferromagnetic material moving in the detecting area.

According to another embodiment, the analyzer may determine that there is the ferromagnetic material moving in the detecting area when a Euclidean norm obtained from outputs of the first differential amplifier, the second differential amplifier, and the third differential amplifier is equal to or greater than a predetermined reference value.

According to another embodiment, the first pair and the third pair may be disposed inside of a first sensor module, and the second pair and the fourth pair may be disposed inside of a second sensor module. Further the fifth pair may be disposed inside of the first sensor module together, and the sixth pair may be disposed inside of the second sensor module together.

In addition, at least one of the directions of the +x, −x, +y, and −y axes may be visually marked on outer surfaces of housings of the first sensor module and the second sensor modules.

Sensor Module Implemented as Wireless Device

Each of the first sensor module and the second sensor module according to the invention may be implemented as a wireless device to be wirelessly connected to the detecting module. In this case, the outputs of the first pair, the second pair, the third pair, and the fourth pair may be amplified individually, converted into digital signals, and then transmitted to the detecting module.

Detection Method by Detector

The invention also provides a method of detecting a ferromagnetic material passing between the first point and the second point by disposing the geomagnetic sensors at the first point and the second point having a width of 2 meters or less. The detection method according to the invention includes: disposing the first to fourth elements respectively comprised of two magnetoresistive elements connected in series between an operating voltage (VCC) and a ground (GND); and when there is a change in outputs of the first to fourth magnetoresistive element pairs, determining that there is a ferromagnetic material passing between the first point and the second point.

The detector according to the invention can detect a movement of a small metal object, such as a handgun, by using a plurality of geomagnetic sensors.

In addition, even when the magnetic field of the detecting area is influenced by a movement of a large metal object, such as a vehicle or an elevator, at a relatively-long distance, the detector according to the invention can separately detect a small metal object passing the detecting area by eliminating the large influence in a common mode.

In the same manner, a change in the geomagnetic field caused by a natural phenomenon, such as an explosion of a black spot of the sun, a movement of the geomagnetic axis, or a magnetic storm, is processed in the common mode, and thus, the operation of detecting a minute change in the magnetic field in the detecting area is not influenced by such a natural phenomenon.

Since the detector according to the invention is designed so as not to react to a change in the magnetic field caused by a relatively-large object in the surrounding area or a change in the geomagnetic field, the geomagnetic sensors of the detector can amplify a microscopic signal, obtained from a movement of a small metal object in the detecting area, at a large magnification factor.

In addition, the detector according to the invention can differentially amplify a change in the magnetic field in the detecting area by applying a bridge offset and a measurement axis offset, by which measurement points of the geomagnetic sensor are expanded to a measurement space, and simultaneously measure a change in the gradient of the magnetic field, thereby sufficiently amplifying a microscopic change in the magnetic field. Accordingly, the detector according to the invention can solve the problem of the sensitivity of a detection signal significantly decreasing with increases in the distance between the sensor and the moving object in the detecting area.

### BRIEF DESCRIPTION OF THE DRAWINGS

The above and other objectives, features, and advantages of the present invention will be more clearly understood from the following detailed description when taken in conjunction with the accompanying drawings, in which:

FIG. 1A is a schematic view illustrating a conventional AMR geomagnetic sensor;

FIG. 1B is a schematic view illustrating a geomagnetic sensor circuit including the geomagnetic sensor illustrated in FIG. 1A;

FIG. 2 is a schematic view illustrating an overall configuration of a detector for a small metal object including geomagnetic sensors according to an embodiment of the invention;

FIG. 3 is a schematic view illustrating the operation of the detector for a small metal object according to the invention;

FIG. 4 is a schematic view illustrating a bridge offset structure;

FIG. 5 is a schematic view illustrating a detector for a small metal object according to another embodiment of the invention;

FIG. 6 is a schematic view illustrating a detector for a small metal object according to the invention disposed in a passage;

FIG. 7 is a flowchart illustrating a method of detecting a ferromagnetic material by the detector according to the invention and

FIG. 8 is a schematic view illustrating a detector for a small metal object according to another embodiment of the invention.

### DETAILED DESCRIPTION OF THE INVENTION

Hereinafter, the invention will be described in more detail with reference to the accompanying drawings.

Referring to FIGS. 2 and 3, a detector 200 using geomagnetic sensors may include a first sensor module 210, a second sensor module 230, and a detecting module 250 to detect a ferromagnetic material passing through a detecting area. A detection method according to the invention is to recognize a change in a magnetic field in response to a movement of a ferromagnetic material. Therefore, strictly, the ferromagnetic material fixedly disposed on the detecting area is not recognized but the movement of the ferromagnetic material is detected. Accordingly, even though it may be described briefly “detecting a ferromagnetic material” hereinafter, it should be interpreted that the movement of the ferromagnetic material is detected or the moving magnetic movement is detected.

The first sensor module 210 and the second sensor module 230 are sensors respectively measuring a change in a magnetic field corresponding thereof and are connected to the detecting module 250. The first sensor module 210 is disposed at a first point p1, the second sensor module 230 is disposed at a second point p2, and a space between the first sensor module 210 and the second sensor module 230 is the detecting area. Here, the first point p1 and the second point p2 are points on the space.

Here, for the convenience of explanation, the detecting area defined by three axes x, y, and z perpendicular to each other, will be described. The operations of the first sensor module 210 and the second sensor module 230 maybe explained on the basis of the three axes x, y, and z defined in a real space. According to the invention, the first point p1 and the second point p2 are disposed on the x axis, since the x axis is a base measurement line.

According to the invention, two axes x and y or three axes x, y, and z are set by disposing the first sensor module 210 and the second sensor module 230 in the real space. Therefore, the x, y, and z are virtual coordinates used to express the detecting area set in the real space. Two or three axis directions have to be predetermined to each of the first sensor module 210 and the second sensor module 230. +x, +y, and +z directions (or +x and +y directions) are set to the first sensor module 210, and −x, −y, and −z (or −x and −y directions) are set to the second sensor module 230. To set the x axis acting as a basis of measurement, the x axis is set by disposing +x of the first sensor module 210 and −x of the second sensor module 230 on the same axis, and the y axis is set by disposing the +y and −y on the same plane (x-y plane). Accordingly, the three axes x, y, and z are set in the real space according to the posture in which the first sensor module 210 and the second sensor module 230 are placed in the detecting area. According to an embodiment, at least one of the +x, −x, +y, and −y axis directions may be visually recognized on an outer surface of a housing of the first sensor module 210 and the second sensor module 230. For example, arrows 210a and 230a indicating the y axis direction are assigned to the first sensor module 210 and the second sensor module 230 in FIG. 6.

When the detecting area defined by the x, y, and z axes (or the x and y axes) are set to the real space, the x-y plane defined by the x axis and the y axis may be set to be parallel to the ground surface or the bottom surface so that measurement can be easily and practically performed, although the x-y plane is not required to be parallel to the ground surface or the bottom surface of a passage. In addition, since the x axis is the base measurement line, the x axis in the x-y plane may be set in a direction optimized for the detection of a ferromagnetic material.

In FIG. 2, a hatched portion indicates the plane of the passage through which persons can walk. In this embodiment, the bottom surface of the passage is set to be parallel to the x-y plane. In addition, when a ferromagnetic material moves along the passage, it is preferable for the x axis to be placed perpendicularly to the passage direction (designated with a bidirectional arrow) in order to reduce the distance to the ferromagnetic material, as illustrated in FIG. 2. However, the x axis may be set to obliquely pass through the passage, and the x-y plane may not be parallel to the passage.

The detector 200 according to the invention has the detecting area in the range of about 1 to 2 meters, and thus, the first point p1 and the second point p2 may be spaced apart by about 1 to 2 meters. For example, as illustrated in FIG. 6, the sensor module 210 and the second sensor module 230 may be disposed on both sides of the passage having a width of 1 meter to detect a small ferromagnetic material passing through the passage. In addition, although the first point p1 and the second point p2 may be disposed on the x axis and +x of the first sensor module 210 and −x of the second sensor module 230 may be disposed on the x axis, an error that may occur in a system disposed at the site is allowable. Even when there is a discrepancy slightly exceeding an error range, each geomagnetic element can recognize a change in the magnetic field with no problem. As described above, the detector according to the invention may operate properly.

Each of the first sensor module 210 and the second sensor module 230 includes a plurality of magnetoresistive element pairs. Two pairs of magnetoresistive elements may be included as illustrated in FIG. 3, or three pairs of magnetoresistive elements may be included as illustrated in FIG. 5. In the embodiment illustrated in FIG. 3, the first sensor module 210 includes a first pair 211 and a third pair 213 and the second sensor module 230 includes a second pair 231 and a fourth pair 233. Each pair has 2 magnetoresistive elements connected in series.

The first to fourth pairs 211, 213, 231, and 233 are electrically connected using the same GND. As will be described later, the detecting module 250 detects change in the magnetic field in the area between the first sensor module 210 and the second sensor module 230 by differentially amplifying the output of the first pair 211 and the output of the second pair 231 and differentially amplifying the output of the third pair 213 and the output of the fourth pair 233.

The resistance of the two magnetoresistive elements connected in series, included in each of the first to fourth pairs 211, 213, 231, and 233, changes in response to a change in an external magnetic field, and a voltage of a connection node, i.e. an output terminal, is changed by voltage distribution. For example, an R1-R2 combination or an R3-R4 combination, connected in series in FIG. 1A, can be a magnetoresistive element pair of the present invention, and connection nodes out+ and out− serve as output terminals. In addition, each measurement axis of the first to fourth pairs 211, 213, 231, and 233 is determined in a method known in the related art, depending on the position of the node through which operating power is supplied and the orientation of the magnetoresistive element.

The first pair 211 outputs Vout 1 from the output terminal in response to a change in the magnetic field, the second pair 231 outputs Vout 2 from the output terminal in response to a change in the magnetic field, the third pair 213 outputs Vout 3 from the output terminal in response to a change in the magnetic field, and the fourth pair 233 outputs Vout 4 from the output terminal in response to a change in the magnetic field.

In the first sensor module 210, the first pair 211 and the third pair 213 are disposed such that the directions of the measurement axis thereof are perpendicular to each other, one corresponding to the +x axis, and the other corresponding to the +y axis.

In the second sensor module 230, the second pair 231 and the forth pair 233 are disposed such that the directions of the measurement axis thereof are perpendicular to each other, one corresponding to the −x axis, and the other corresponding to the −y axis.

A virtual space defined by the x, y, and z axes may be set in a real space by disposing the direction of the +x axis of the first pair 211 and the direction of the -axis of the second pair 231 on a single axis (i.e. x axis). In contrast, the direction of the +y axis of the third pair 213 and the direction of the −y axis the fourth pair 233 are not positioned on a single axis, due to a measurement axis offset, to be described later, although the direction of the +y axis of the third pair 213 and the direction of the −y axis the fourth pair 233 are disposed on the same x-y plane.

In addition, each of the first sensor module and the second sensor module may include three pairs of magnetoresistive elements in order to set the x, y, and z axes in the detecting area and measure a change in the magnetic field in the directions of the three axes. In a detector 500 illustrated in FIG. 5, each of a first sensor module 510 and a second sensor module 530 includes three pairs of magnetoresistive elements. The first sensor module 510 further includes a fifth pair 511, in addition to the configuration of the first sensor module 210, and the second sensor module 530 further includes a sixth pair 531, addition to the configuration of the second sensor module 230. The fifth pair 511 has a measurement axis on the +z axis and outputs Vout 5 from an output terminal, and the sixth pair 531 has a measurement axis on the −z axis and outputs Vout 6 from an output terminal.

In addition, each of the first sensor module 210 and the second sensor module 230 has a separate housing. The first to fourth pairs 211, 213, 231, and 233, as well as a direct current (DC) power circuit supplying power to the first to fourth pairs 211, 213, 231, and 233 and the like, are disposed inside of the housing.

The detecting module 250 detects a ferromagnetic material by recognizing a change in the magnetic field in the x axis and the y axis using Vout 1 and Vout 3, i.e. outputs of the first sensor module 210, and Vout 2 and Vout 4, i.e. outputs of the second sensor module 230. Since a significant change in the output of at least one of Vout 1, Vout 2, Vout 3, and Vout 4 indicates a significant change in the magnetic field in the detecting area, there may be a variety of methods of recognizing a change in a magnetic field using the outputs of the first sensor module 210 and the second sensor module 230.

For example, the detecting module 250 includes a first differential amplifier 251, a second differential amplifier 253, and an analyzer 255, and detects a ferromagnetic material by differentially amplifying a signal of each axis using the differential amplifiers. The first differential amplifier 251 differentially amplifies the output Vout 1 of the first pair 211 and the output Vout 2 of the second pair 231 and outputs a differentially amplified signal to the analyzer 255. The second differential amplifier 253 differentially amplifies the output Vout 3 of the third pair 213 and the output Vout 4 of the fourth pair 233 and outputs a differentially amplified signal to the analyzer 255. Since the invention is intended to detect a minute change in the magnetic field in the detecting area, the levels of Vout 1, Vout 2, Vout 3, and Vout 4 will definitely be minute. Accordingly, the invention differentially amplifies the minute outputs of the first sensor module 210 and the second sensor module 230 using the first differential amplifier 251 and the second differential amplifier 253.

The differential amplifier 251 and the second differential amplifier 253 may be differential amplifier circuits well-known in the art. In other ways, the first differential amplifier 251 and the second differential amplifier 253 may be implemented in the form that a processor like a digital signal processing (DSP) chip and software operating on the said processor are combined.

The analyzer 255 detects a ferromagnetic material using output signals of the first differential amplifier 251 and the second differential amplifier 253. For example, when the output of at least one of the first differential amplifier 251 and the second differential amplifier 253 is equal to or higher than a predetermined reference value, the analyzer 255 may determine that a ferromagnetic material is present in the detecting area. In other ways, the analyzer 255 may obtain the Euclidean norm of the outputs of the first differential amplifier 251 and the second differential amplifier 253 and determine that a ferromagnetic material is present in the detecting area, on the basis of whether or not the Euclidean norm is equal to or higher than a predetermined reference value, since the outputs of the first differential amplifier 251 and the second differential amplifier 253 are vectors in different direction. In addition, when the signals of the first differential amplifier 251 and the second differential amplifier 253 are lower than the reference value, the analyzer 255 may determine the signals as noise.

The analyzer 255 may be implemented as a typical logic circuit or may be implemented in the form that a processor like a DSP chip and software operating on the said processor are combined. In other ways, the analyzer 255 may be implemented as software operating on an operating system (OS) program of a computer-like apparatus.

If each of the first sensor module 210 and the second sensor module 230 includes three pairs of magnetoresistive elements, as illustrated in FIG. 5, the detecting module 250 may further include a third differential amplifier 551 to differentially amplify the output of the fifth pair 511 and the output of the sixth pair 531. In addition, the analyzer 255 detects a ferromagnetic material using output signals of the first differential amplifier 251, the second differential amplifier 253 and the third differential amplifier 551.

Hereinafter, a method of detecting a ferromagnetic material using the first sensor module 210 and the second sensor module 230 according to the invention will be described.

Measurement of Space Using Bridge Offset

Referring to FIG. 4, the first pair 211 and the second pair 231 are forming a bridge circuit and are differentially amplified by the first differential amplifier 251. When compared to the geomagnetic sensor U1 illustrated in FIG. 1A, the first pair 211 and the second pair 231 are disposed to be spatially distanced by a bridge offset distance. According to this arrangement, a bridge offset space may be a detecting area, so that a microscopic or minute change in the magnetic field in the detecting area can be amplified.

The change in the magnetic field in the detecting area acts on the first pair 211 and the second pair 231 in different directions, so that the output Vout 1 of the first pair 211 and the output Vout 2 of the second pair 231 are signals having different signs. Eventually, Vout 1 and Vout 2 are differentially amplified by the first differential amplifier 251 to amplify the outputs of the magnetoresistive elements caused by a minute change in the magnetic field. If the magnitude of the output of the first differential amplifier 251 is equal to or greater than a reference value, the analyzer 255 recognizes the ferromagnetic material. The bridge offset can prevent a rapid loss of the signal due to an increase in the distance between the magnetoresistive element and the measurement point at which the magnetic field is changed. Regardless of the position in the passage at which a change in the magnetic field occurs, signals can be objected without significant losses.

Since a change in the magnetic field at a position being close to the first pair 211 and the second pair 231 while not being between the first pair 211 and the second pair 231 acts on the first pair 211 and the second pair 231 in the same direction, the output Vout 1 of the first pair 211 and the output Vout 2 of the second pair 231 are signals having the same sign. Vout 1 and Vout 2 are subtracted while being differentially amplified by the first differential amplifier 251, thereby lowering the detecting sensitivity.

In addition, due to the bridge offset, a change in the magnetic field caused by a large ferromagnetic material located outside of the detecting area may act on the first pair 211 and the second pair 231 in a common mode, i.e. the change may acts on the first pair 211 and the second pair 231 in substantially the same direction and magnitude.

In the common mode, even from outside of the detecting area, the change in the magnetic field acts with a significant magnitude in the detecting area, so that the outputs Vout 1 and Vout 2 are signals having substantially the same magnitude and having the same sign. Accordingly, since Vout 1 and Vout 2 are subtracted while being differentially amplified, there is substantially no output of the first differential amplifier 251.

As described above, although there is no output of the first differential amplifier 251 due to the bridge offset in the common mode, the analyzer 255 may further include a common mode detecting part (not shown) to detect a common mode output using outputs of the first pair 211 and the second pair 231. For example, when a sum of the output Vout 1 of the first pair 211 and the output Vout 2 of the second pair 231 is equal to or greater than a predetermined magnitude, the common mode detecting part (not shown) may determine that there is a change in the magnetic field in common mode.

Measurement of Gradient of Magnetic Field Using Measurement Axis Offset

When an object formed of metal moves, a permanent magnetization component and an induced magnetization component are changed in the magnetic field. Such magnetization components change the gradient of the surrounding magnetic field. If only the first pair 211 and the second pair 231 are disposed, it is difficult to measure the gradient of the magnetic field of the y axis. The present invention further includes the third pair 213 and the fourth pair 233 in order to measure a change of the gradient of the magnetic field in the direction of the y axis.

Referring to FIG. 3, a “measurement axis offset” is provided between the measurement axes +y and −y of the third pair 213 and the fourth pair 233, differently from the first pair 211 and the second pair 231, the measurement axes of which are disposed on the x axis.

The use of the measurement axis offset makes it possible to measure a change in the magnetic field including the gradient of the magnetic field in the direction of the y axis in the detecting area. To measure the gradient of the magnetic field in the detecting area, it is advantageous to place the two measurement axis as far away as the detecting area. Accordingly, the third pair 213 and the fourth pair 233 can detect a change in the gradient of the minute magnetic field using the measurement axis offset.

In addition, since the third pair 213 and the fourth pair 233 are distanced from each other by the measurement axis offset, a passage of travel in the direction of the y axis can be obtained. In other words, when the x axis is set to intersect the passage, none of the third pair 213 and the fourth pair 233 may be disposed on the passage.

According to the present invention, it is possible to improve the sensitivity of the minute magnetic field in the detecting area by simultaneously applying the third pair 213 and the fourth pair 233, to which the measurement axis offset is applied, together with the first pair 211 and the second pair 231 in the bridge offset,

Sensor Module Including 3 Axis-Magnetoresistive Element Pairs

The first sensor module 510 and the second sensor module 530 of FIG. 5 set the detecting area on the three axes of the x, y, and z axes and measure a change in the magnetic field on the three axes. Accordingly, the first sensor module 510 further includes the fifth pair 511 in addition to the configuration of the first sensor module 210, and the second sensor module 530 further includes the sixth pair 531 in addition to the configuration of the second sensor module 230.

When the first sensor module 510 is located at the first point p1 and the second sensor module 530 is located at the second point p2, a measurement axis offset is caused between the +z axis of the fifth pair 511 and the −z axis of the sixth pair 531, like the “measurement axis offset” between the measurement axes +y and −y of the third pair 213 and the fourth pair 233. Accordingly, the fifth pair 511 and the sixth pair 531 can measure a change in the magnetic field and the gradient of the magnetic field in the direction of the z axis. In the same manner, when a change in the magnetic field caused from outside of the detecting area acts on the third pair 213 and the fourth pair 233 in the common mode, the same is applied to the fifth pair 511 and the sixth pair 531 in the common mode.

A detecting module 550 of a detector 500 illustrated in FIG. 5 further includes a third differential amplifier 551 in addition to the first differential amplifier 251 and the second differential amplifier 253. The third differential amplifier 551 differentially amplifies the output Vout 5 of the fifth pair 511 and the output Vout 6 of the sixth pair 531 and outputs a differentially amplified signal to the analyzer 255.

If the magnitude of the output of one of the first differential amplifier 251, the second differential amplifier 253, and the third differential amplifier 551 is equal to or greater than the reference value, the analyzer 255 may determine that a ferromagnetic material is detected. Also, if the magnitudes of the outputs of all of the first differential amplifier 251, the second differential amplifier 253, and the third differential amplifier 551 are respectively equal to or greater than the reference value, the analyzer 255 may determine that a ferromagnetic material is detected. As an alternative, like obtaining a Euclidean norm, when a sum of the squares of the outputs of all of the first differential amplifier 251, the second differential amplifier 253, and the third differential amplifier 551 is equal to or greater than the reference value, the analyzer 255 may determine that a ferromagnetic material is detected. Or a square root of the sum can be used to compare with the reference value.

According to an embodiment, the detecting module 550 illustrated in FIG. 5 may further include a common mode detecting part. The common mode detecting part may determine whether or not a change in the magnetic field corresponds to the common mode by determining whether or not a sum of the output Vout 1 of the first pair 211 and the output Vout 2 of the second pair 231 is equal to or greater than a predetermined magnitude, determining whether or not a sum of the output Vout 3 of the third pair 213 and the output Vout 4 of the fourth pair 233 is equal to or greater than a predetermined magnitude, or determining whether or not a sum of the output Vout 5 of the fifth pair 511 and the output Vout 6 of the sixth pair 531 is equal to or greater than a predetermined magnitude.

In addition, these features of the invention are applied to the detection methods of the detectors 200 and 500 described with reference to FIGS. 2 to 6.

Referring to FIG. 7, the detection method according to the invention includes: step S701 of disposing the plurality of magnetoresistive element pairs 211, 213, 231, 233, 511, and 531 in the detecting area with the bridge offset and the measurement axis offset as illustrated in FIGS. 3 and 5; step S703 of differentially amplifying outputs of the magnetoresistive element pairs 211, 213, 231, 233, 511, and 531 using the first to third differential amplifiers 251, 253, and 551; and step S705 of determining whether or not there is a change in a magnetic field in response to a movement of a ferromagnetic material in the detecting area, on the basis of the outputs of the first to third differential amplifiers 251, 253, and 551.

Wireless Connection of First Sensor Module 210 and Second Sensor Module 230

The first sensor module 210 and the second sensor module 230 may be implemented as wireless devices so as to be easily disposed on the detecting area.

Referring to FIG. 8, a first sensor module 810 and a second sensor module 830 may be connected to a detecting module 850 via a wireless channel, such as a Bluetooth, a wireless LAN (Local Area Network), or the like, to provide outputs of the first to fourth pairs 211, 213, 231, and 233 to the detecting module 850 as analog signals or by converting the outputs into digital signals.

To convert the outputs into digital signals, the first sensor module 810 includes: the first and third amplifiers 811 and 813 amplifying the outputs of the first pair 211 and the third pair 231, respectively; a first converter 815 converting the amplified signals into digital signals; and a first wireless interface 817 transmitting outputs of the first converter 815 to the detecting module 850. In the same manner, the second sensor module 830 includes: the second and fourth amplifiers 831 and 833 amplifying the outputs of the second pair 213 and the fourth pair 233, respectively; a second converter 835 converting the amplified signals into digital signals; and a second wireless interface 837 transmitting outputs of the second converter 835 to the detecting module 850.

In a corresponding manner, the detecting module 850 requires a third wireless interface 851, by which the detecting module 850 can be connected to the first wireless interface 817 and the second wireless interface 837. When the wireless devices are provided as above, the first to fourth pairs 211, 213, 231, and 233 cannot be connected to the same ground (GND). Accordingly, the detecting module 850 sets reference values of the outputs of the first to fourth pairs 211, 213, 231, and 233, and the first and second differential amplifier 853 and 855 differentially amplify changed values of the outputs of the first to fourth pairs 211, 213, 231, and 233 by software.

Although the exemplary embodiments of the present invention have been described for illustrative purposes, those skilled in the art will appreciate that various modifications, additions and substitutions are possible, without departing from the scope and spirit of the present invention as disclosed in the accompanying claims.

What is claimed is:

1. A detector disposed at a first point and a second point within a width of 2 meters to detect a ferromagnetic material passing through a detecting area between the first point and the second point, the detector comprising:
first to fourth magnetoresistive element pairs respectively comprised of two magnetoresistive element connected in series between an operating voltage and a ground, wherein the first pair is disposed at the first point such that a measurement axis thereof is in a direction of +x axis directed to the second point, the second pair is disposed at the second point such that a measurement axis thereof is in a direction of −x axis, the third pair is disposed at the first point such that a measurement axis thereof is in a direction of +y axis perpendicular to the +x axis, and the fourth pair is disposed at the second point such that a measurement axis thereof is in a direction of y axis perpendicular to the −x axis; and
a detecting module determining that there is a ferromagnetic material moving in the detecting area when there is a change in outputs of the first to fourth pairs.

2. The detector according to claim 1, wherein the detecting module includes:
a first differential amplifier differentially amplifying the outputs of the first pair and the second pair;
a second differential amplifier differentially amplifying the outputs of the third pair and the fourth pair; and
an analyzer determining that there is the ferromagnetic material moving in the detecting area when outputs of the first differential amplifier and the second differential amplifier are detected.

3. The detector according to claim 2, wherein the analyzer determines that there is the ferromagnetic material moving in the detecting area when a Euclidean norm obtained from outputs of the first differential amplifier and the second differential amplifier is equal to or greater than a predetermined reference value.

4. The detector according to claim 2, wherein the detecting module further includes a common mode detector detecting a common mode when signals having the same magnitude and the same sign are output from the first pair and the second pair,
wherein the common mode is a state in which a change in a magnetic field caused by a movement of a large ferromagnetic material outside of the detecting area is acting on the detecting area.

5. The detector according to claim 2, further comprising:
a fifth pair disposed at the first point such that a measurement axis thereof is in a direction of +z axis perpendicular to the +x axis and the +y axis;
a sixth pair disposed at the second point such that a measurement axis thereof is in a direction of −z axis; and
a third differential amplifier differentially amplifying voltages of output nodes of the fifth pair and the sixth pair,
wherein the analyzer determines that there is the ferromagnetic material moving in the detecting area when the outputs of at least two differential amplifiers, selected from among the first differential amplifier, the second differential amplifier, and the third differential amplifier, are detected.

6. The detector according to claim 5, wherein the analyzer determines that there is the ferromagnetic material moving in the detecting area when a Euclidean norm obtained from outputs of the first differential amplifier, the second differential amplifier, and the third differential amplifier is equal to or greater than a predetermined reference value.

7. The detector according to claim 1, further comprising;
a first sensor module accommodating the first pair and the third pair therein; and
a second sensor module accommodating the second pair and the fourth pair therein,
wherein at least one of the directions of the +x, −x, +y, and −y axes is visually marked on outer surfaces of housings of the first sensor module and the second sensor modules.

8. The detector according to claim 7, wherein each of the first sensor module and the second sensor module comprises a wireless device to be wirelessly connected to the detecting module,
wherein the outputs of the first pair, the second pair, the third pair, and the fourth pair are converted into digital signals before being transmitted to the detecting module.

9. A method of detecting a ferromagnetic material passing between a first point and a second point by disposing geomagnetic sensors at the first point and the second point having a width of 2 meters or less, the method comprising:
disposing first to fourth magnetoresistive element pairs respectively comprised of two magnetoresistive elements connected in series between an operating voltage and a ground, wherein the first pair is disposed at the first point such that a measurement axis thereof is in a direction of +x axis directed to the second point, the second pair is disposed at the second point such that a measurement axis thereof is in a direction of −x axis, the third pair is disposed at the first point such that a measurement axis thereof is in a direction of +y axis perpendicular to the +x axis, and the fourth pair is disposed at the second point such that a measurement axis thereof is in a direction of −y axis perpendicular to the −x axis; and
determining that there is a ferromagnetic material moving in the detecting area when there is a change in outputs of the first to fourth pairs.
